(19) United States
(12) Patent Application Publication
(10) Pub. No.: US 2003/0090257 A1
(43) Pub. Date: May 15, 2003

(54) Method and apparatus for load testing electrical systems

(76) Inventor: Lawrence H. Howes, Santa Barbara, CA (US)

Correspondence Address: IRELL & MANELLA LLP, 840 NEWPORT CENTER DRIVE, SUITE 400, NEWPORT BEACH, CA, 92660, US

(21) Appl. No.: 10/004,124

(22) Filed: Oct. 30, 2001

(51) Int. Cl. G01R 1/00

(52) U.S. Cl. 324/127

(57) ABSTRACT

The invention relates to an apparatus and method for load testing electrical systems using a transformer having its primary windings connected to a power source and its secondary windings coupled to the device under test. The test apparatus may be used to test high power switching circuits to be implemented in three-phase power systems. One aspect of the invention involves eliminating the load resistor or load bank, which is normally used to simulate the working load when testing AC switching devices. In one embodiment, the load bank function is replaced by the secondary winding of a step-down transformer, and the voltage across the device under test is boosted using a second power source. In another embodiment, the primary current of the transformer is controlled to regulate the current in the device under test.

### BACKGROUND

1. Field

The invention relates generally to electrical test systems and more particularly, to an apparatus and method for testing electrical devices by using a current injection transformer to drive full load current through the devices to be tested.

2. Description of the Related Art

Semiconductor devices, such as silicon controlled rectifiers (SCRs), diodes, transistors, etc. are typically tested during manufacturing to determine the quality and performance of the device. Such devices may be implemented as switches or in switching circuits, such as a static transfer switch (STS).

One example of such performance or quality testing is a high-power STS test. During normal operation, the current flowing through the STS generates substantial heat inside the STS. In order to properly simulate true operating conditions, it is desirable to duplicate this high-heat enviroment during the testing period. It is also desirable to apply high voltages to the STS so as to test the breakdown and insulation performance of the STS. Given that the breakdown voltage of most insulation materials is adversely affected by elevated temperature, it is also desirable to have a testing environment in which both a high voltage and a high current are applied to the STS under test. To this end, FIG. 1 illustrates a conventional system 100 for testing an STS.

The power source 110 of FIG. 1 supplies a current to a resistor bank 130 via switch 120. Where the switch 120 is used in high power circuits (not shown), the power source 110 may supply 480 VAC (rms) to the resistor bank 130 (for example, of 1.2 ohms) that draws, for example, up to 400 A of current. While this method is capable of applying both a high current as well as a high voltage across the STS, a large amount of power will be dissipated in the form of heat. To illustrate, in the example of FIG. 1 a three-phase resistive load bank, implemented as the resistor bank 130, would consume 332 KW of electric power. Such use of electric power requires the test facility to provide the electrical wiring capacity to deliver the required electric power safely and efficiently. In addition, with the deregulation of electric companies, the cost for electric power has escalated, resulting in increased overhead for high power testing.

Accordingly, there is a need in the technology to provide an apparatus and method for overcoming the aforementioned problems.

### BRIEF SUMMARY OF THE INVENTION

The invention comprises a method and apparatus for testing a quality of an electrical circuit. The method comprises providing a first power source, connecting a step-down transformer having a primary side and a secondary side to said first power source, and connecting a second power source to said secondary side of said step-down transformer. The method further comprises connecting said electrical circuit to said secondary side of said step-down transformer, and providing a predetermined current and a predetermined voltage to said electrical circuit over a test period.

### BRIEF DESCRIPTION OF THE DRAWINGS

FIG. 1 illustrates a typical switch testing system of the prior art.

FIG. 2 illustrates one embodiment of a current injection test system provided in accordance with the principles of the invention.

FIG. 3 illustrates a second embodiment of a current injection test system provided in accordance with the principles of the invention.

FIG. 4 illustrates a third embodiment of a current injection test system provided in accordance with the principles of the invention.

FIG. 5 illustrates a fourth embodiment of a current injection test system consistent with the invention.

FIG. 6A is a flow diagram of one embodiment of a method of current control used in conjunction with the invention.

FIG. 6B is a diagram of certain aspects of the method of current control of FIG. 6A, according to one embodiment.

FIG. 7 is a flow diagram of certain aspects for another embodiment of the method of current control of FIG. 6A.

FIG. 8A illustrates a waveform which relates to yet another embodiment of the method of current control of FIG. 6A.

FIG. 8B is a flow diagram of another embodiment of the method of current control of FIG. 6A.

FIG. 9 is a chart illustrating one example of the test data obtained for testing a three-phase switching circuit provided in accordance with the principles of the invention.

### DETAILED DESCRIPTION OF THE PREFERRED EMBODIMENTS

The invention relates to an apparatus and method for testing electrical devices using a transformer having its primary windings connected to the source and its secondary windings coupled across the unit under test (“UUT”). In one embodiment, the invention may be used to test high-power electrical devices. This test apparatus may be used to determine a performance quality and/or a design quality of a single or multi-phased switching circuit, where the design quality may simply be based on a pass-fail scale. Alternatively, the design quality may be based on a graded scale indicating the likely durability or strength of the UUT. While in one embodiment, the UUT is a solid-state SCR switch employed in an STS, any high-power electrical device that does not consume much power itself may be tested using the principles of this invention.

One aspect of the invention involves eliminating the load resistor or load bank, which is normally used to simulate the working load when testing high-power switching devices. Eliminating the load bank greatly reduces the amount of power consumed during testing. Reduction in power consumption by a factor of more than 100 is possible. In one embodiment, the load bank function is replaced by the secondary winding of a step-down transformer. In this manner, high current may be applied across the UUT, without consumption of large amounts of power.

Another aspect of the invention relates to boosting the voltage across the secondary winding of the step-down transformer by attaching a high voltage source to one side of the secondary winding. In this manner, the insulation properties of the UUT may be tested, while also limiting power dissipation, as will be described in more detail below.

Another aspect of the invention relates to controlling the primary current of the transformer to regulate the current in the switch device being tested. In one embodiment, current control is automated using feedback control loop circuitry. In one embodiment of this control loop, a variable autotransformer is used to drive a fixed toriodal transformer to adjust the current through the test device. In another embodiment of the control loop, thyristor devices are used to control current by varying the conduction angle of the alternating current through the thyristor device. In yet another embodiment of the control loop, pulse width modulation is used to generate a composite signal having a desired average power which is supplied to the primary winding of a transformer.

Principles of Operation

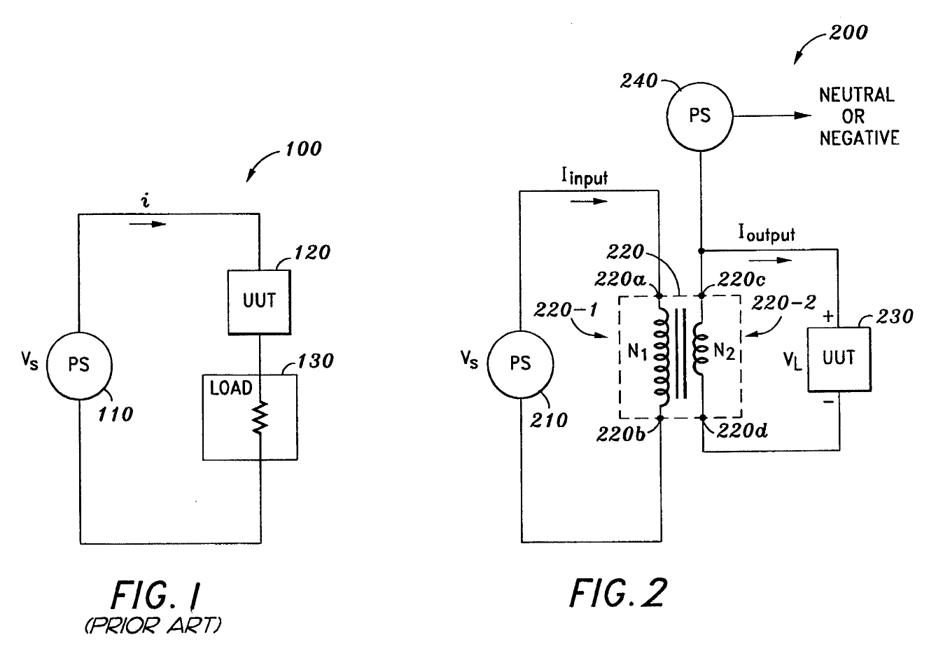

FIG. 2 is a schematic diagram of one embodiment of a current injection test system 200 in accordance with the principles of the invention. The current injection test system 200 comprises a first power source 210 connected across the transformer primary 220-1, a transformer 220, and a UUT 230 that is connected across the transformer secondary 220-2. In one embodiment, the first power source 210 is an adjustable AC power source. The UUT 230 may be a silicon controlled rectifier (SCR), an insulated-gate bipolar transistor (IGBT), a metal-oxide semiconductor field-effect transistor (MOSFET), a MOSFET controlled thyristor (MCT), a solid state switch, a relay, a contact, a circuit breaker, a fuse, a mechanical switch or any other suitable switching element as known in the technology. The UUT 230 may also be a combination of any one or more of the above-described devices.

In one embodiment, the transformer primary 220-1 has windings N1 and terminals 220a and 220b, which are connected to the power source 210. Similarly, the transformer secondary 220-2 has windings N2 and terminals 220c and 220d, which are connected to the UUT 230 and the second power source 240, which in one embodiment is a fixed AC power source. Moreover, in one embodiment, the transformer 220 is a step-down injection transformer.

The turns ratio of the transformer 220 may be represented as N₁:N₂, which represents the ratio of the number of turns in the coil on the transformer primary 220-1 to the number of turns in the coil on the transformer secondary 220-2. As will be recognized by those skilled in the art, where N₁ is greater than N₂, the transformer functions as a step-down transformer. The relationship of voltage across the transformer primary 220-1 (“V₁”) to the voltage across the transformer secondary 220-2 (“V₂”) is directly proportional to the ratio of the turns N₁:N₂ and may be represented as:

$$\frac{{V}_{1}}{{V}_{2}} = \frac{{N}_{1}}{{N}_{2}}$$

In high power applications, a conventional power source 110 typically supplies 480 VAC (rms) or more, with most of the power being dissipated in the resistor bank 130. For example, assume a current of 400 A is required across the UUT with an available power source of 480 VAC. A conventional system would thus require a resistance of 1.20 ohms. For example,

$$\begin{matrix}{I}_{output} ( rms ) = {V}_{s} ( rms ) / {R}_{L} \\ {I}_{output} ( rms ) = 480 / 1.20 \\ = 400 A .\end{matrix}$$

where,

Iₒᵤₜₚᵤₜ(rms)=the current to the UUT,

Vₛ(rms)=the voltage from the power source, and

R_{L}=the resistance across the resistor bank 130.

In addition, Iᵢₙₚᵤₜ(rms)=Iₒᵤₜₚᵤₜ(rms), where Iᵢₙₚᵤₜ(rms) is the current drawn from the power source.

Thus, the power required by this three-phase circuit, assuming a power factor (PF) of 1.0, would be,

$$\begin{matrix}P = {V}_{s} ( rms ) * {I}_{input} ( rms ) * {( 3 )}^{\frac{1}{2}} * PF \\ = 480 ( 400 ) ( 1.73 ) ( 1.0 ) \\ = 332 KW .\end{matrix}$$

In contrast, using current injection as illustrated in FIG. 2:

$$\begin{matrix}{V}_{s} ( rms ) = 480 \\ {V}_{L} = ( N2 / N1 ) ( 480 ) \\ = ( 1 / 100 ) ( 480 ) \\ = 4.80 volts .\end{matrix}$$

where,

V_{L}=the voltage across the secondary side of the transformer 220 and R_{UUT} is the resistance of the unit under test.

In addition,

Iₒᵤₜₚᵤₜ(rms)=V_{L}(rms)/R_{UUT}.

To produce the 400 A required current, assume that R_{UUT} is 0.012 ohms,

$$\begin{matrix}{I}_{output} ( rms ) = 4.80 / 0.012 \\ = 400 A\end{matrix}$$

whereas,

$$\begin{matrix}{I}_{input} ( rms ) = ( N2 / N1 ) {I}_{output} ( rms ) \\ = ( 1 / 100 ) ( {I}_{output} ( rms ) ) \\ = 4.00 A \\ Power = 4.8 ( 400 ) ( 1.73 ) ( 1.0 ) \\ = 3.32 KW .\end{matrix}$$

As a result, it can be observed that the current drawn from the source Vₛ is [1/(N1/N2)] of that required by the circuit being tested. In the example above, it translates into a reduction in current by a factor of 100.

As the above example illustrates, the first power source 210 and the current injection transformer may not provide the required high voltage for testing the breakdown and insulation properties of the UUT. The second power source 240 may thus be used to simulate the high voltage environment. While in one embodiment the second power source is a fixed 480 VAC power source, other power sources may also be connected across the transformer secondary 220-2 to increase the voltage applied across the UUT. Where the second power source 240 is a high voltage source, the operating voltage for the transformer secondary 220-2 may be established and controlled by the second power source 240, since the voltage produced across the transformer secondary 220-2 is much lower by comparison.

It should be noted that the second power source 240 provides relatively little power to the UUT, where the only load current drawn from this source is the current required by the internal control circuits of the UUT.

In this manner, the invention significantly reduces the power requirements for testing high-power devices by using the transformer 220 to provide the required high current to the UUT, while the second power source 240 provides the required high voltage.

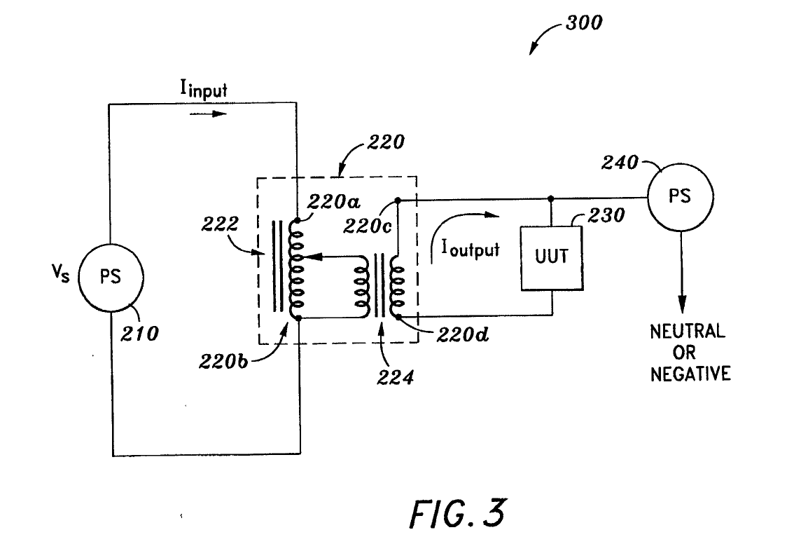

FIG. 3 illustrates a second embodiment of a current injection test system provided in accordance with the principles of the invention. The system 300 of FIG. 3 is identical to that of FIG. 2, with the exception of the addition of a variac 222. In this embodiment, the transformer 220 includes the variac 222 and the transformer 224. The variac 222 may be used to adjust the amount of voltage across the transformer primary 220-1 of the transformer circuit 224. In one embodiment, the variac utilizes a potentiometer to produce a percentage of the voltage available from the power source 210. It should further be appreciated that the variac 222 may be connected to a feedback circuit which compares the current in the UUT 230 to a desired current. If the UUT 230 current differs from the desired current then the variac 222 may include circuitry known in the art which can drive the variac 222 to the position which supplies the correct current.

Implementation of Test Apparatus

As mentioned above, one embodiment of the present invention determines a quality of the UUT. In one embodiment, the quality is either a pass or a fail indicator depending on whether the UUT functioned as expected during and/or after the burn-in period. In another embodiment, the quality is a grade of the UUT's performance during and/or after the burn-in period. It should further be appreciated that the quality may be any performance characteristic of the UUT that is desirable to know. For example, the invention may be used to determine the amount of time required for the circuit breaker to trip when subjected to varying levels of overload current. In another embodiment, the invention could be used in conjunction with other equipment to determine the rate of temperature increase for a high-power device.

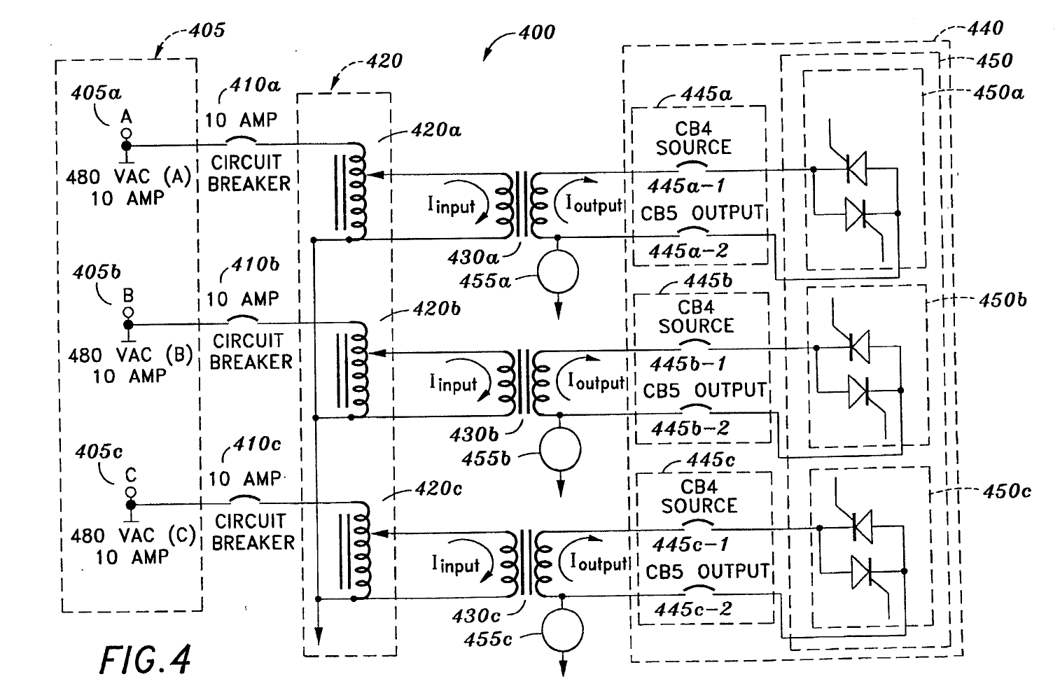

FIG. 4 illustrates a third embodiment of a current injection test system provided in accordance with the principles of the invention. In this embodiment, the UUT 440 comprises a three-phase switching circuit 450, including switch circuits 450a, 450b and 450c (collectively, switching circuits 450), which correspond to phases A, B and C of a power system (not shown) in which the switching circuit 450 will be implemented. The UUT 440 may also include circuit breakers 445a, 445b, 445c that are coupled to each of the switch circuits 450a, 450b and 450c. Switch circuit 450 may also include a first circuit breaker, for example, 445a-1 in the case of switch circuit 445a, that is coupled to the source, and a second circuit breaker, for example, 445a-2, that is coupled to the output.

The test system 400 further comprises three phased sources 405a, 405b and 405c, which correspond to the three phases A, B and C of a power system. Each source 405a, 405b and 405c is coupled to a transformer, such as toroid 430a, 430b and 430c respectively. In one embodiment, each source 405a, 405b and 405c may also be coupled to a circuit breaker 410a, 410b and 410c respectively. A variac 420a, 420b and 420c (collectively, variac 420) may be coupled between each circuit breaker 410a, 410b and 410c and the toroid 430a, 430b and 430c respectively. While the embodiment depicted in FIG. 4 shows the first source 405 as being comprised of phased sources 405a, 405b and 405c, it should be appreciated that single or other multi-phased sources may also be used in place thereof.

The test system 400 depicted in FIG. 400 also includes a second source, which may similarly be comprised of a single phased source, or multi-phased sources, such as three phased sources 455a, 455b and 455c.

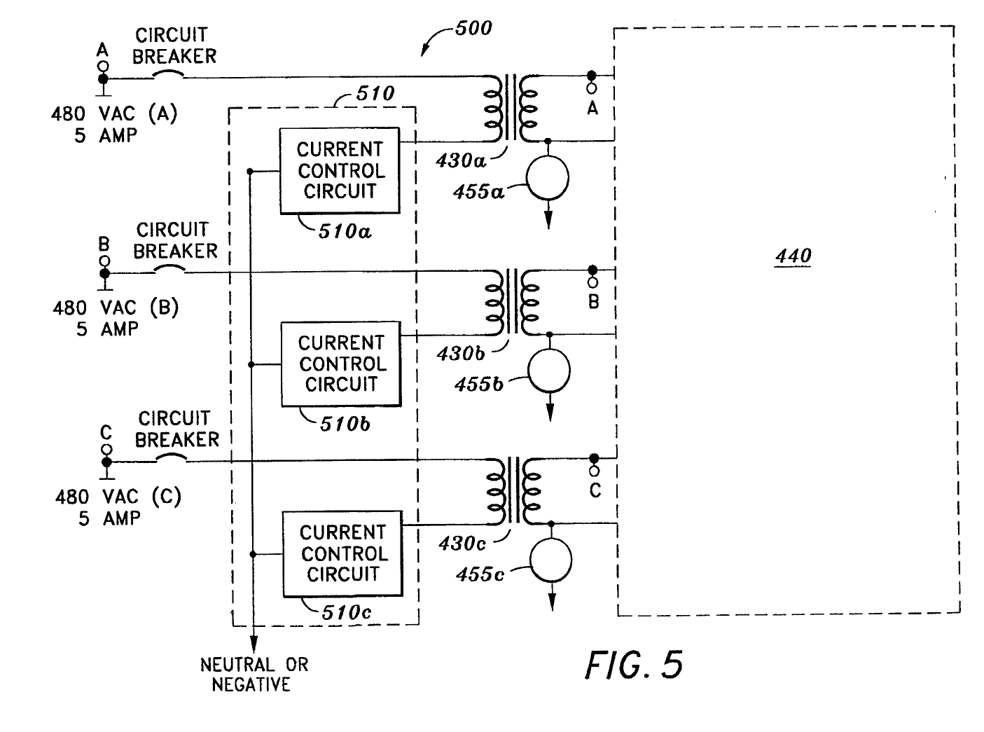

FIG. 5 illustrates-an alternate embodiment of a current injection test system provided in accordance with the principles of the invention. The current injection test system 500 as shown in FIG. 5 is generally identical to the system 400 of FIG. 4, with the exception that test system 500 includes current control circuits 510a, 510b and 510c (collectively, current control circuits 510) coupled to the primary side of each toroid 430a, 430b and 430c, respectively. As with the variac 222 of FIG. 3, the current control circuits 510 may be used to control the amount of current supplied to the primary windings of each toroid 430a, 430b and 430c. A more detailed discussion of the various embodiments of the current control circuits 510 will follow.

Current Control

While controlling the flow of current through a UUT may be done manually, it may be desirable to automate the current control process since variations in the circuit's resistance can cause larger variations in the test current. These resistive variations may originate within the UUT, the current injection circuit, the interconnecting cables between the current injection circuit and the UUT, and/or any combination thereof. Thus, automating the current control process enables a UUT to be provided with a relatively constant current over the entire test period. To this end, a current control circuit 510 may be connected to the primary winding of an injection transformer, as shown in FIG. 5.

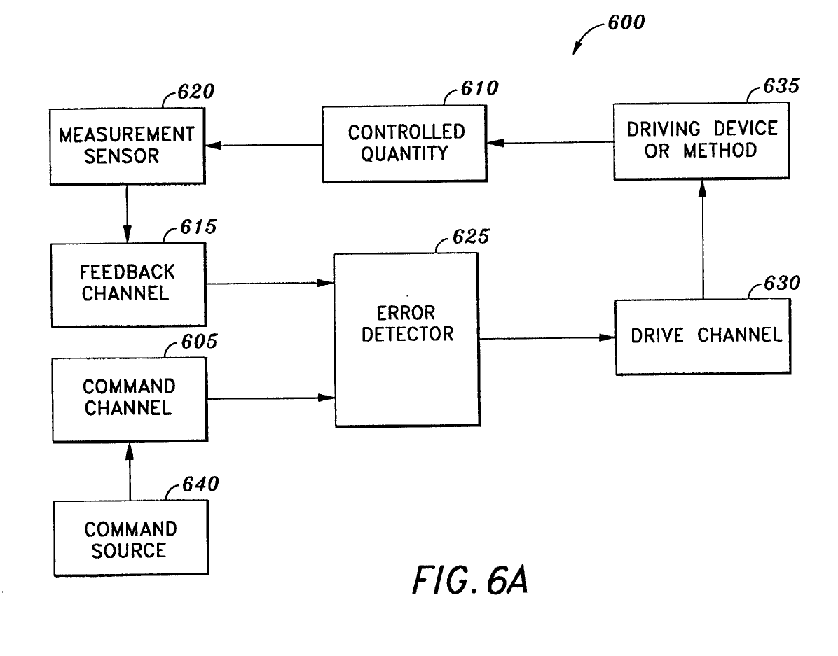

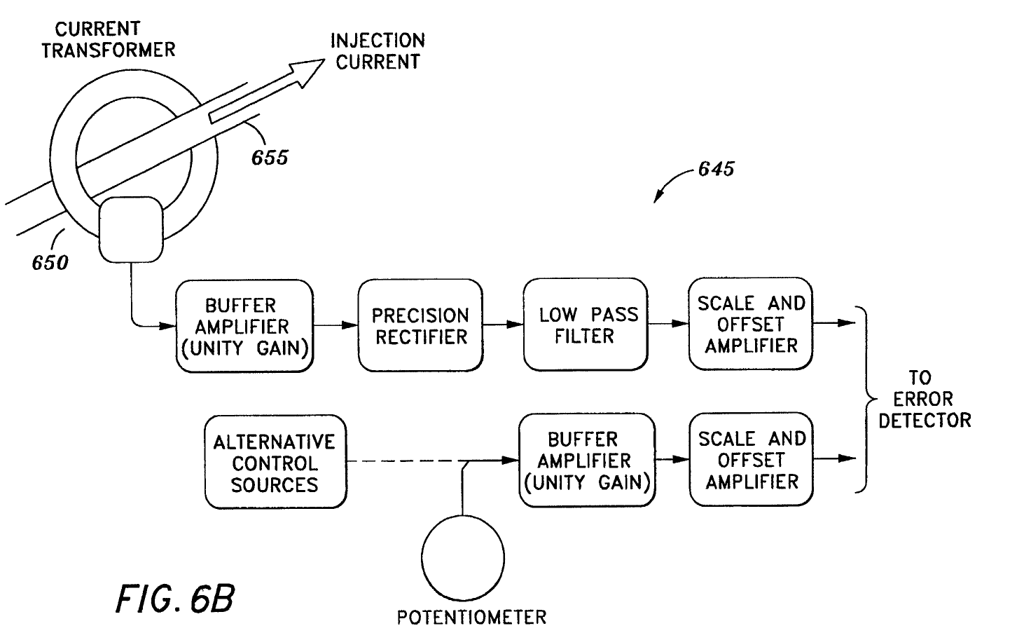

In one embodiment, current control circuit 510 includes a closed control loop, such as control loop 600 depicted in FIG. 6A. The command channel 605 of FIG. 6A may provide a signal (the “command signal”) which represents the desired value for the controlled quantity 610. In one embodiment, the controlled quantity 610 represents the current through the UUT (Iₒᵤₜₚᵤₜ). The command signal may be represented with either analog or digital methods, as commonly known in the art.

Still referring to FIG. 6A, the feedback channel 615 may provide a signal (the “feedback signal”) which represents the value of the controlled quantity 610 as detected by the measurement sensor 620, and may also be represented with either analog or digital methods. The feedback signal and command signal are then supplied to the error detector 625, which produces a “drive signal” to the drive channel 630. The drive signal may then be applied to a driving device or method 635 to appropriately affect the value of the controlled quantity 610. In this manner, the control loop 600 may be used to achieve and maintain a state of equilibrium, in which the command signal and feedback signal are essentially equal.

The command source 640 may be the mechanism by which an equipment operator directs the command channel 605. In one embodiment, the command source is comprised of an analog panel control mechanism. In another embodiment, the command source 640 comprises transmission and receiving circuitry to enable an equipment operator to remotely enter command information.

In one embodiment, the feedback signal is generated by a current transformer circuit, such as current transformer circuit 645, as shown in FIG. 6B. In this embodiment, the current transformer circuit 645 is comprised of a toroidial transformer 650 which may, in turn, be connected to other various other circuits as shown in FIG. 6B. In the embodiment of FIG. 6B, the primary winding 655 of this transformer 650 passes through the center of the toroid, and the primary winding 655 is the cable carrying the load current, labeled as Iₒᵤₜₚᵤₜ in FIGS. 2-4. Thus, in this embodiment, as a result of the load current (Iₒᵤₜₚᵤₜ), an AC voltage is induced in the secondary winding of the transformer 650, with this voltage being proportional to Iₒᵤₜₚᵤₜ. Additional circuitry, as shown in FIG. 6B, may be electrically connected to the transformer 650 to scale the amplitude of the feedback signal and convert it into an equivalent DC signal. Moreover, additional circuitry not shown may be employed to convert the feedback signal from an expression of average current to an expression of rms current, as more typically used for equipment testing.

In one embodiment, the driving device or method 635 is an eletro-mechanical variable autotransformer (“variac”), driven by stepper motors that are used to control the current across the primary windings of a current injection transformer, such as the previously discussed transformer 220. In one embodiment, this driving device is used to drive variac 222 or variacs 420a, 420b and 420c.

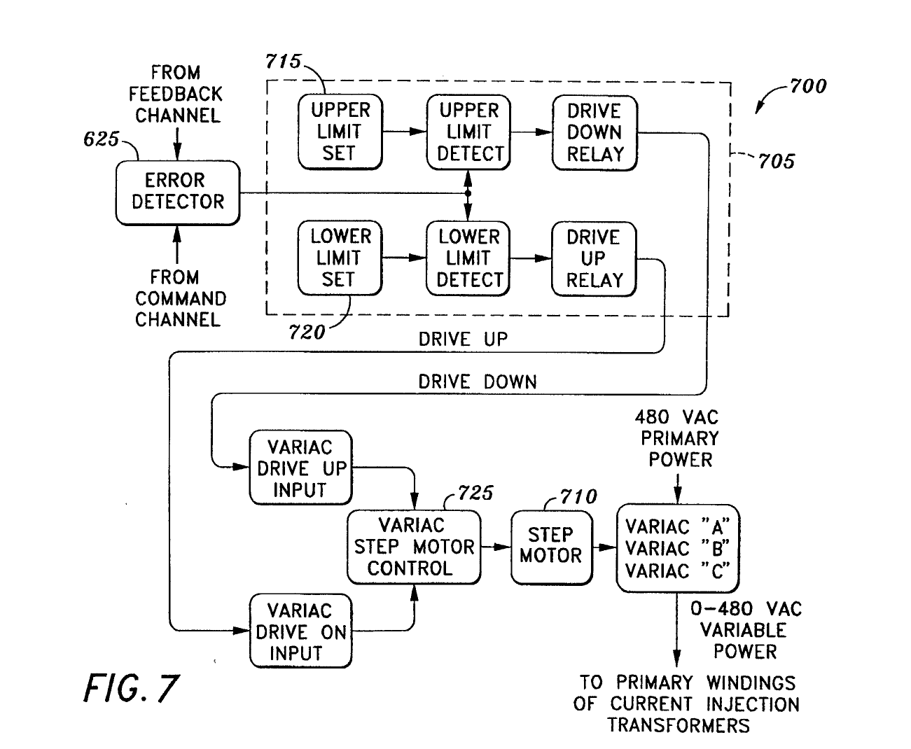

One implementation of the driving device 635 directing a variac is shown in FIG. 7. As discussed above, the feedback channel 615 and the command channel 605 both provide signals to the error detector 625. In addition, the driving device 700 of FIG. 7 also include a “deadband” function 705 to prevent premature wearing of the variac stepper motor 710. In particular, the variac stepper motor 710 is only directed to drive the variac either up or down when the error detected by error detector 625 exceeds some threshold. In the embodiment shown in FIG. 7, an upper limit threshold 715 and a lower limit threshold 720 are both set. The signal provided by the error detector 625 is tested against both the upper threshold 715 and lower threshold 720 and an appropriate signal is sent to the variac stepper motor control circuit 725, which in turn directs the variac stepper motor 710 to either increase or decrease the current accordingly. As shown in FIG. 7, in one embodiment the variac to which the driving device 700 may be connected is variac 420 as previously described above. In addition, the upper and lower thresholds may be based on a percentage of the full rated output current (Iₒᵤₜₚᵤₜ). Where this is the case, the upper threshold 715 and lower threshold 720 may be between 2 and 3 percent of Iₒᵤₜₚᵤₜ. However, other percentages may also be used depending on the desired accuracy.

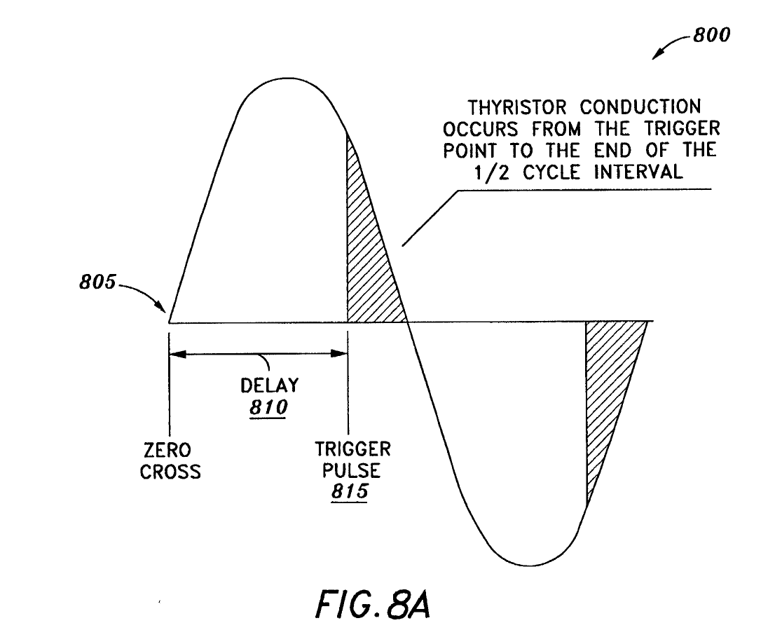

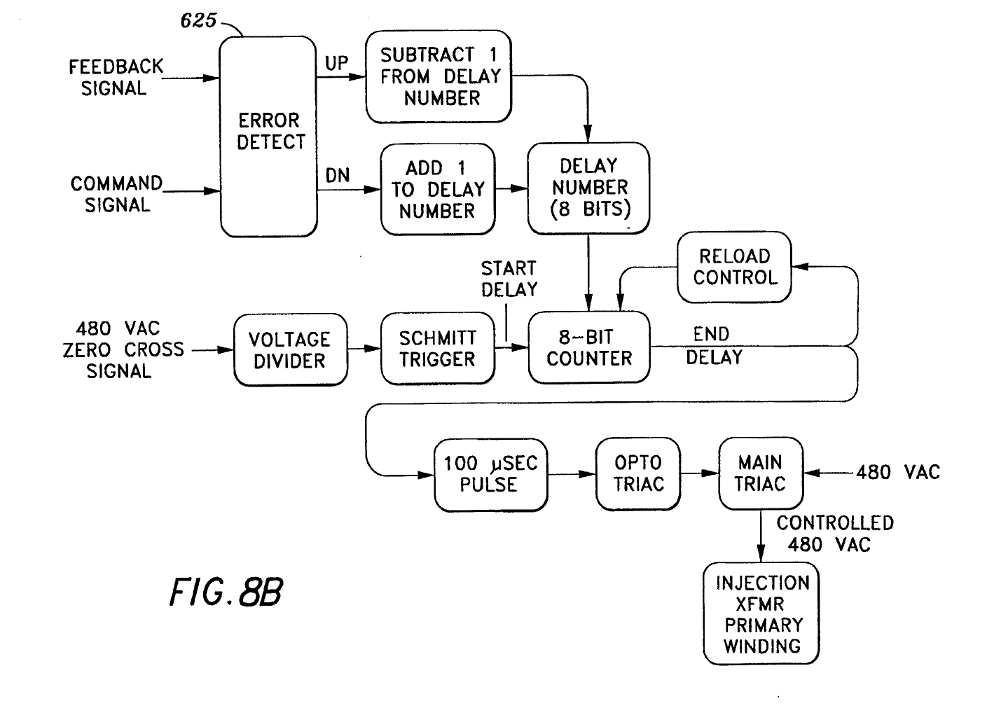

In another embodiment, the function of the drive channel 635 may be performed using a control method which makes use of thyristor devices. With this method, a sample of power from an AC line is used to start a precision timer, which in one embodiment is located within a microcomputer. Referring now to FIG. 8A in which a waveform is depicted, the power sample taken serves as a line synchronizing pulse that causes the timer to start at the beginning of a given AC cycle, such as at point 805. It should be appreciated that, while the waveform of FIG. 8A may be a 60 Hertz waveform, other waveform frequencies may also be used.

Once the timer is started, it may run for a predetermined delay period 810, which may vary from 0 to 8.33 milliseconds, in the case of a 60 Hertz waveform. When the delay period 810 expires, a microcomputer may then generate a trigger pulse 815 which directs the thyristor device to apply the primary power to the current injection system. In one embodiment, the trigger pulse 815 is a 100 microsecond pulses.

One aspect of this current control method makes use of the fact that by varying the delay period 810, it is possible to vary the alternating current conduction angle through the thyristor device from 0 to 180 degrees for each half cycle of the primary AC waveform. Varying the thyristor conduction angle, in turn, serves to vary the injection test current (Iₒᵤₜₚᵤₜ) from 0 to its full rated output. In this manner, the output current can be automatically adjusted to maintain a predetermined value. Referring now to FIG. 8B, in which a flow diagram of the thyristor current control method is depicted. As before, the feedback signal and command signal are supplied to the error detector 625. The error detector 625 compares the values of the two signals to determine if the result is positive, negative or zero. If the result is zero, no corrective action need be taken and the system may reset for the next comparison operation. If the value supplied by the error detector is positive, it may indicate that the that the injection test current (Iₒᵤₜₚᵤₜ) is greater than the desired test current. In such an instance, the delay period 810 is increased by 1 unit, thereby reducing the conduction angle of the thyristor devices. In one embodiment, each unit of the delay period 810 causes the conduction angle to vary by approximately 0.7 degrees.

Conversely, where the difference provided by the error detector 625 is negative, the injection test current (Iₒᵤₜₚᵤₜ) may be smaller than the desired test current. In this case, the delay period 810 may be decreased by one unit, thereby increasing the conduction angle by approximately 0.7 degrees, according to one embodiment. It should be appreciated that the conduction angle may be altered by some other increment, depending on the desired sensitivity of the system.

With the conduction angle increment set at 0.7 degrees and the process of FIG. 8B repeating 60 times per second, the maximum conduction angle change per second is (60*0.7) 42 degrees. Thus, using the process of FIGS. 8A-8B the injection test current (Iₒᵤₜₚᵤₜ) can be altered from its minimum to its maximum (or vice versa) in approximately 4.25 seconds, according to one embodiment.

Yet another method for driving the current in the control loop 600 is based on the idea of pulse width modulation (“PWM”) In particular, PWM involves the electronic ‘summing’ of two primary signals to create a third composite signal. In one embodiment, the two primary signals are added using linear power semiconductor devices, such as IGBTs, power MOSFETs or other similar power semiconductor devices capable of linear signal control (hereinafter, a “linear power device”). The average power in the composite signal may then be controlled by controlling the power in either of the two primary signals. In one embodiment, one of the primary signals is a primary power source which may be either a DC power source or a low frequency AC power source. The other primary signal may then be a control signal, such as a pulse waveform. This signal will be referred to hereafter as the control waveform.

The average power in the composite signal may be controlled by varying some aspect of the control waveform. While in one embodiment, the amplitude of the control waveform may be altered, the frequency or the pulse width of the waveform may also be varied. In any event, varying any of the control waveform properties will result in varying the average power of the composite signal on a proportional basis.

It may also be desirable to reduce any discontinuities in the waveform of the composite signal. In one embodiment, a passive low-pass filter is installed between the linear power device and the primary winding of the injection transformer. It may further be desirable to set the control waveform at a high frequency to relax the design requirements for the low-pass filter.

As mentioned above, the primary power source may either be a DC source or a low-frequency AC source. Where a DC source is used for the control signal, the control loop 600 may also act to synthesize a corresponding AC waveform by varying the controlled pulse quantity in a sinusoidal manner, as well as varying the waveform characteristics as discussed above to achieve the desired test current. In one embodiment, synthesizing an AC control signal can be done with conventional linear circuit elements using balanced signal modulation methods, while in another embodiment a microcomputer is used to perform the various computations required. For example, the sinusoidal value of the control waveform is “numerically modulated” by the signal provided by the error detector 625, before being applied to the linear power devices. In one embodiment, this is done by multiplying the sine value, at any given point on the waveform, by a fraction ranging from 0 to 1 which represents the desired fraction of a “full throttle” signal for the control loop. Using this method, the “throttle percentage” is controlled by the output of the control loop's error detector 625, but the sine value is automatically generated at a rate necessary to produce the desired frequency in the output waveform.

In contrast, where the primary power source is an AC waveform, this waveform is merely modulated with a pulse waveform whose pulse quantity is controlled directly by the output of the control loop error detector 625, according to one embodiment.

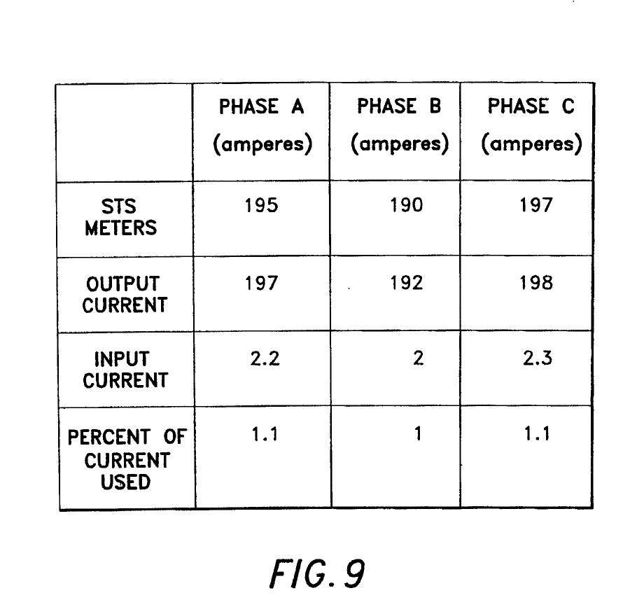

Referring now to the chart of FIG. 9, in which there is presented test data obtained from testing a three-phase switching circuit in accordance with one embodiment of the present invention. In this embodiment, a burn-in test was conducted on an STS at full rated current (200 amps). In one embodiment, the test is conducted at the full rated current for at least two hours for each configuration of the internal circuit breakers. Thus, the total test time may reach or exceed eight hours for a given STS. Referring still to FIG. 9, current was recorded at the input side and the output side for all three phases. The test data of FIG. 9 indicates that the percentage of current supplied by the power source is roughly 1% of the current supplied to the STS.

As mentioned previously, one aspect of the present invention is to provide a method and apparatus for reducing the cost of testing high power switching devices. To this end, Table 1 below illustrates the cost savings in implementing the test equipment provided in accordance with the principles of the invention.

TABLE 1
Current Injector Power Savings

| | | Col. 3 |
|---|---|---|
| Col. 1 | Col. 2 | Period Required to |
| Power | Power | Recover Cost of Current |
| Cost | Requirement | Injection System |
| ($/kwh) | Ratio | (weeks) |
| 0.15 | 2/100 | 1.79 |
| 0.10 | 2/100 | 2.68 |
| 0.05 | 2/100 | 5.37 |

Column 1 of Table 1 lists three scenarios of various power costs ranging from $0.15 per kilowatt-hour to $0.05 per kilowatt-hour. Column 2 contains the ratio of the power required by a current injection system in accordance with the principles of the present invention, to the power required for an STS burn using the traditional loadbank method. Column 3 provides an estimate of the number of weeks required to recover the cost of a current injector system operated in accordance with the principles of the present invention. As a point of reference, Column 3 is based on the power a conventional system requires to burn one 166 KVA three-phase static transfer switches (STS) over an eight hour period. In addition, Column 3 assumes a current injection system costs $3500 and that two 8-hour burns per day are conducted over a five-day week. Moreover, Column 3 assumes prior ownership of the conventional loadbank system.

Although the invention has been described in terms of a certain preferred embodiment, other embodiments apparent to those skilled in the art are also within the scope of this invention. Accordingly, the scope of the invention is intended to be defined only by the claims which follow.

What is claimed is:

1. An apparatus for testing a quality of an electrical circuit comprising:
a first power source;
a step-down transformer having a primary side and a secondary side, said primary side connected to said first power source; and,
a second power source connected to the secondary side of said step-down transformer,
the electrical circuit to be connected to the secondary side of said step-down transformer, said electrical circuit to be provided with a predetermined current and a predetermined voltage over a test period.

2. The apparatus of claim 1, further comprising a control circuit connected to said first power source to control a voltage across the primary side of said step-down transformer.

3. The apparatus of claim 2, wherein said first power source is a multi-phase alternating current power source, and said electrical circuit is a high-power switching device.

4. The apparatus of claim 1, wherein said first power source substantially provides said predetermined current to said electrical circuit.

5. The apparatus of claim 4, wherein said second power source substantially provides said predetermined voltage to said electrical circuit over the test period.

6. The apparatus of claim 5, wherein said second power source includes a first terminal and a second terminal, said first terminal to be connected to said secondary side of the step-down transformer, said second terminal to be connected to a common neutral.

7. The apparatus of claim 1, wherein primary side of said step-down transformer includes a number of turns in a coil which is greater than a number of turns in a coil on said secondary side.

8. The apparatus of claim 2, wherein said control circuit comprises an automated feedback control loop.

9. The apparatus of claim 8, wherein said automated feedback control loop includes a thyristor device controlling a conduction angle, said conduction angle to be adjusted to maintain said predetermined current at an essentially constant level.

10. The apparatus of claim 8, wherein said automated feedback control loop uses pulse width modulation to maintain said predetermined current at an essentially constant level.

11. The apparatus of claim 1, wherein said electrical circuit is a semiconductor device implemented as a switching circuit.

12. The apparatus of claim 1, wherein said predetermined amount of current is at least 100 amperes, and said first power source is at least a 208 VAC power source.

13. The apparatus of claim 1, wherein said quality of said electrical circuit is a pass-fail indicator.

14. The apparatus of claim 1, wherein said quality is at least one of a thermal resistance quality, an electrical conductance quality and an insulation quality.

15. The apparatus of claim 1, wherein said quality of said electrical circuit is a grade representing the likelihood that said electrical circuit will fail.

16. A method of testing a quality of an electrical circuit comprising:
providing a first power source;
connecting a step-down transformer having a primary side and a secondary side to said first power source;
connecting a second power source to said secondary side of said step-down transformer;
connecting said electrical circuit to said secondary side of said step-down transformer; and,
providing a predetermined current and a predetermined voltage to said electrical circuit over a test period.

17. The method of claim 16, further comprising connecting a control circuit to said first power source to control a voltage across the primary side of said step-down transformer.

18. The method of claim 17, wherein providing said first power source comprises providing a multi-phase alternating power source, said electrical circuit to be a high-power switching device.

19. The method of claim 16, wherein said first power source substantially provides said predetermined current to said electrical circuit.

20. The method of claim 19, wherein said second power source substantially provides said predetermined voltage to said electrical circuit over the test period.

21. The method of claim 20, wherein connecting said second power source comprises connecting the second power source to said secondary side of said step-down transformer, said second power source to include a first terminal and a second terminal, said first terminal to be connected to said secondary side of the step-down transformer, said second terminal to be connected to a common neutral.

22. The method of claim 16, wherein connecting a step-down transformer comprises connecting a step-down transformer having a primary side and a secondary side to said first power source, said primary side having a number of turns in a coil which is greater than a number of turns in a coil on said secondary side.

23. The method of claim 17, wherein connecting a control circuit to said first power source comprises connecting an automated feedback control loop to said first power source to control the voltage across the primary side of said step-down transformer.

24. The method of claim 23, wherein said automated feedback control loop includes a thyristor device controlling a conduction angle, said conduction angle to be adjusted to maintain said predetermined current at an essentially constant level.

25. The apparatus of claim 23, wherein said automated feedback control loop uses pulse width modulation to maintain said predetermined current at an essentially constant level.

26. The method of claim 16, wherein connecting said electrical circuit to said secondary side comprises connecting said electrical circuit to said secondary side of said step-down transformer where said electrical circuit is a semiconductor device implemented as a switching circuit.

27. The method of claim 16, wherein providing the predetermined current to said electrical circuit comprises providing at least 100 amperes to said electrical circuit over the test period, said first power source to be at least a 208 VAC power source.

28. The method of claim 16, further comprising:
identifying said quality of said electrical circuit, wherein said quality is a pass-fail indicator.

29. The method of claim 13, further comprising identifying said quality of said electrical circuit, wherein said quality is at least one of a thermal resistance quality, an electrical conductance quality and an insulation quality.

30. A method of testing a quality of a high-power electrical device comprising:
providing a first power source, said first power source to provide a first voltage across a primary side of a step-down transformer;
connecting the primary side of the step-down transformer to said first power source, said step-down transformer to include the primary side and a secondary side, said primary side having a number of turns in a primary coil which is greater than a number of turns in a secondary coil on said secondary side;
connecting a second power source to said secondary side of said step-down transformer, said second power source to provide a second voltage across the secondary side of said step-down transformer;
connecting said electrical device to said secondary side of said step-down transformer;
connecting a control circuit to said first power source to control said first voltage;
providing a predetermined current and a predetermined voltage to said device over a test period; and
identifying said quality of said electrical device, wherein said quality is at least one of a thermal resistance quality, an electrical conductance quality and an insulation quality.
